(19) United States
(12) Patent Application Publication
(10) Pub. No.: US 2023/0209804 A1
(43) Pub. Date: Jun. 29, 2023

(54) CAPACITOR AND DRAM DEVICE INCLUDING THE SAME

(71) Applicant: SAMSUNG ELECTRONICS CO., LTD., SUWON-SI (KR)

(72) Inventors: Cheoljin Cho, Hwaseong-si (KR); Yukyung Shin, Suwon-si (KR); Changhwa Jung, Seoul (KR); Hyunjun Kim, Gwacheon-si (KR); Hanjin Lim, Seoul (KR)

(21) Appl. No.: 17/935,148

(22) Filed: Sep. 26, 2022

(30) Foreign Application Priority Data
Dec. 29, 2021 (KR) 10-2021-0190836

(51) Int. Cl. H01L 27/108

(52) U.S. Cl. CPC H01L 27/10814; H01L 27/10823

(57) ABSTRACT

A capacitor is described. The capacitor includes a lower electrode, a dielectric layer structure disposed on the lower electrode, and an upper electrode disposed on the dielectric layer structure. The dielectric layer structure includes a first dielectric layer, a second dielectric layer contacting the first dielectric layer, and a third dielectric layer contacting the second dielectric layer. Each of the first to third dielectric layers includes a material with a crystalline structure. The second dielectric layer includes an oxide having ferroelectric or antiferroelectric properties, and the second dielectric layer includes a material in which at least two different crystal phases are mixed.

### CROSS-REFERENCE TO RELATED APPLICATION

This application claims priority under 35 USC § 119 to Korean Patent Application No. 10-2021-0190836, filed on Dec. 29, 2021, in the Korean Intellectual Property Office (KIPO), the disclosure of which is incorporated by reference herein in its entirety.

### TECHNICAL FIELD

Embodiments relate to a capacitor and a DRAM device including the same. More particularly, embodiments relate to a capacitor having a high capacitance and a DRAM device including the same.

### DISCUSSION OF THE RELATED ART

Capacitors are used in many electronic devices as constituent components of circuits. Capacitors store charges, and are used in several applications. For example, capacitors are used signal smoothing, signal coupling and decoupling, capacitance sensors, and the like. Capacitors may also be used in memory storage; the charged state and the discharged state may represent a ‘0’ value or a ‘1’ value.

In a DRAM device, one memory cell may include a transistor and a capacitor. Charged capacitors gradually lose charge over time. In many cases, the DRAM device includes a refresh circuit to periodically refresh the capacitor's charge state. To ensure reliable data, capacitors are being developed with increased capacitance. However, while greater capacitance can be achieved with increased density and reduced thickness of the dielectric layers, such changes may also result in leakage currents. There is a need in the art for a capacitor structure with increased capacitance without increased leakage currents.

### SUMMARY

Example embodiments provide a capacitor having a high capacitance. Other example embodiments provide a DRAM device including a capacitor having a high capacitance.

According to an embodiment, a capacitor includes a lower electrode; a dielectric layer structure disposed on the lower electrode, the dielectric layer structure including a first dielectric layer, a second dielectric layer contacting the first dielectric layer, and a third dielectric layer contacting the second dielectric layer; and an upper electrode disposed on the dielectric layer structure, wherein each of the first to third dielectric layers includes a material with a crystalline structure, the second dielectric layer includes an oxide having ferroelectric or antiferroelectric properties, and wherein the second dielectric layer includes a material with at least two different crystal phases.

According to another embodiment, a capacitor includes a lower electrode; a dielectric layer structure disposed on the lower electrode, the dielectric layer structure including a first dielectric layer, a third dielectric layer, and a second dielectric layer adjacent to the first dielectric layer and the third dielectric layer; and an upper electrode disposed on the dielectric layer structure, wherein the dielectric layer structure has a thickness of 30 Å to 60 Å in a thickness direction perpendicular to an upper surface of the lower electrode, wherein the second dielectric layer includes hafnium oxide or zirconium oxide, and the second dielectric layer includes one material in which at least two different crystal phases are mixed, and wherein a thickness of the second dielectric layer is less than 50% of a total thickness of the dielectric layer structure.

According to an embodiment, a DRAM device includes a cell transistor disposed on a substrate, the cell transistor including a gate structure, a first impurity region, and a second impurity region; a bit line structure electrically connected to the first impurity region and including a plurality of bit line structures; a contact plug contacting the second impurity region, the contact structure disposed between adjacent bit line structures of the plurality of bit line structures; and a capacitor disposed on the contact structure, the capacitor electrically connected to the second impurity region, wherein the capacitor comprises: a lower electrode; a dielectric layer structure disposed on the lower electrode, the dielectric layer structure including a first dielectric layer, a second dielectric layer, and a third dielectric layer, the second dielectric layer disposed adjacent to the first dielectric layer and the third dielectric layer; and an upper electrode disposed on the dielectric layer structure, wherein the second dielectric layer includes hafnium oxide or zirconium oxide, the second dielectric layer includes a material in which a tetragonal crystal phase and an orthorhombic crystal phase are mixed, and wherein the tetragonal crystal phase and the orthorhombic crystal phases included in the second dielectric layer are stacked on along a surface of the first dielectric layer.

In example embodiments, the capacitor including the dielectric layer structure may have an increased capacitance.

### BRIEF DESCRIPTION OF THE DRAWINGS

Example embodiments will be more clearly understood from the following detailed description taken in conjunction with the accompanying drawings. FIGS. 1 to 14 represent example embodiments as described herein.

FIG. 1 is a cross-sectional view that illustrates a capacitor in accordance with example embodiments;

FIG. 2 is a plan view of a second dielectric layer included in the dielectric layer structure;

FIG. 3 is a cross-sectional view that illustrates a capacitor in accordance with example embodiments;

FIG. 4 is a cross-sectional view that illustrates a capacitor in accordance with example embodiments;

FIG. 5 is a graph that illustrates a dielectric constant according to concentrations of the first crystal phase and the second crystal phase in a second dielectric layer;

FIG. 6 is a cross-sectional view that illustrates a capacitor in accordance with example embodiments;

FIG. 7 is a cross-sectional view that illustrates a capacitor in accordance with example embodiments;

FIG. 8 is a cross-sectional view that illustrates a capacitor in accordance with example embodiments;

FIG. 9 is a cross-sectional view that illustrates a capacitor in accordance with example embodiments;

FIGS. 10 to 13 are cross-sectional views that illustrate a method of manufacturing a capacitor in accordance with example embodiments; and

FIG. 14 is a cross-sectional view that illustrates a DRAM device having a capacitor structure in accordance with example embodiments.

### DESCRIPTION OF EMBODIMENTS

Hereinafter, embodiments will be described in detail with reference to the accompanying drawings. Like reference symbols in the drawings may denote like elements, and to the extent that a description of an element has been omitted, it may be understood that the element is at least similar to corresponding elements that are described elsewhere in the specification.

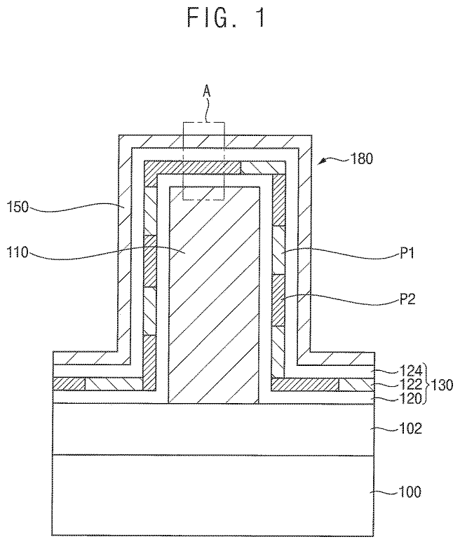

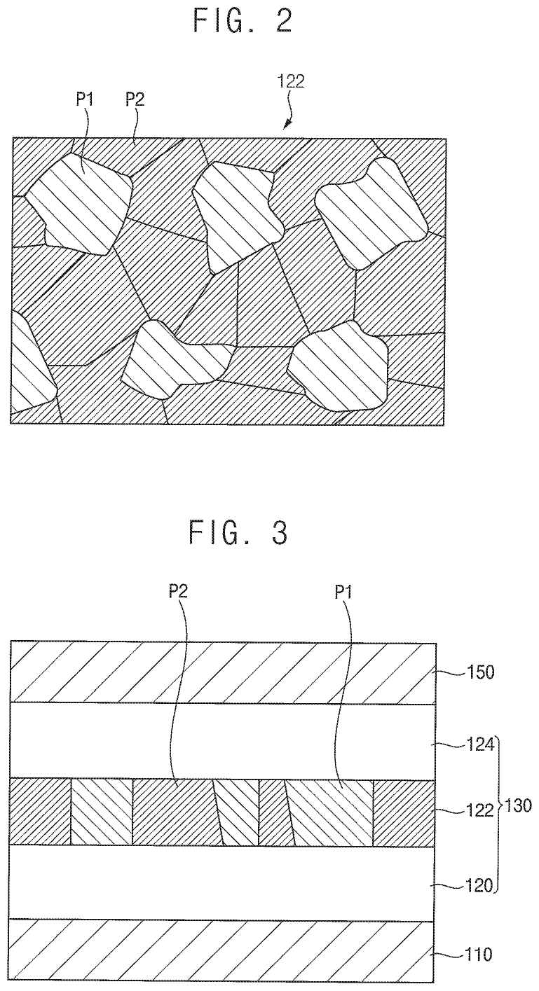

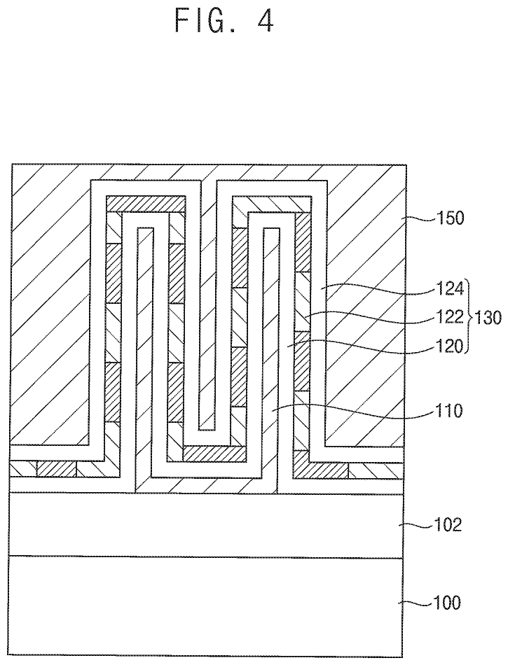

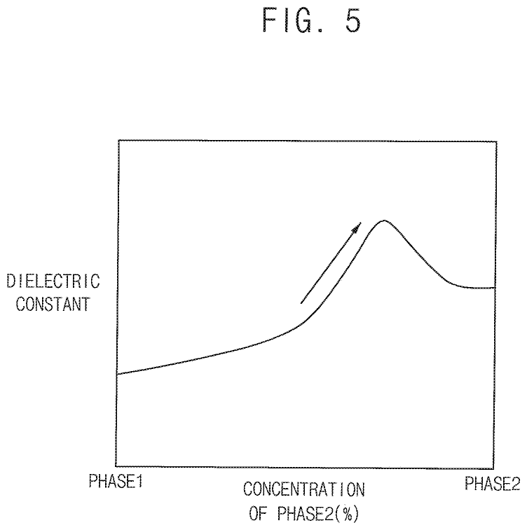

FIG. 1 is a cross-sectional view that illustrates a capacitor in accordance with example embodiments. FIG. 2 is a plan view of a second dielectric layer included in the dielectric layer structure. FIG. 3 is a cross-sectional view that illustrates a capacitor in accordance with example embodiments. FIG. 4 is a cross-sectional view that illustrates a capacitor in accordance with example embodiments.

In the embodiment illustrated in FIG. 1, the capacitor may have a lower electrode having pillar shape. In the FIG. 3, the capacitor may have a lower electrode having a flat plate shape.

Referring to FIGS. 1 to 3, the capacitor 180 may include a lower electrode 110, a dielectric layer structure 130, and an upper electrode 150. The capacitor 180 may be formed on a lower structure 102 on a substrate 100. In some embodiments, the lower structure 102 may include a transistor, a contact plug, a conductive line, and an insulating interlayer covering the transistor, the contact plug and the conductive line.

The lower electrode 110 and the upper electrode 150 may each include a metal, a metal nitride, or a conductive oxide. In example embodiments, the lower electrode 110 and the upper electrode 150 may each include titanium nitride (TiN), titanium (Ti), tantalum (Ta), tantalum nitride (TaN), ruthenium (Ru), tungsten, tungsten nitride, Nb, NbN, indium tin oxide (ITO), Ta doped SnO2, Nb doped SnO2, Sb doped SnO2, V doped SnO2, or a combination thereof. The lower electrode 110 and the upper electrode 150 may be formed of the same material or may include different materials.

The lower electrode 110 may have various three-dimensional structures. In example embodiments, the lower electrode 110 may have a three-dimensional structure such as a cylinder shape or a pillar shape.

As shown in FIG. 1, the lower electrode 110 may have the pillar shape. As shown in FIG. 3, the lower electrode 110 may have a flat shape; e.g., may be two-dimensional structure without a protrusion in a third dimension. As shown in FIG. 4, the lower electrode 110 may have a cylindrical shape. The capacitor shown in FIG. 3 may have substantially the same structure as the enlarged cross-sectional view of portion A in FIG. 1.

The dielectric layer structure 130 may be interposed between the lower electrode 110 and the upper electrode 150. The dielectric layer structure 130 may cover an upper or outer surface of the lower electrode 110, and may contact the lower electrode 110. The dielectric layer structure 130 may be disposed along a surface profile of the lower electrode 110. As shown in FIG. 3, when the lower electrode 110 has a flat plate shape, the dielectric layer structure 130 may be formed on an upper surface of the lower electrode 110 and also have a two-dimensional shape. Alternatively, as shown in FIGS. 1 and 4, when the lower electrode 110 has the pillar shape or the cylinder shape, the dielectric layer structure 130 is formed along the surface of the lower electrode 110 and may have a three-dimensional shape.

The dielectric layer structure 130 may include a plurality of stacked dielectric layers. For example, the dielectric layer structure 130 may have a structure in which a first dielectric layer 120, a second dielectric layer 122 and a third dielectric layer 124 are stacked. The first to third dielectric layers 120, 122, and 124 may include a crystalline structure. By contrast, when an amorphous material is included in each of the first to third dielectric layers 120, 122, and 124, a dielectric constant of the dielectric layer structure 130 may be decreased, and leakage currents may be increased at a low operating voltage (e.g., −1V to 1V) of a device. Accordingly, embodiments may not include an amorphous material in the first to third dielectric layers 120, 122, and 124.

The second dielectric layer 122 may be an oxide with ferroelectric or antiferroelectric properties depending on electric fields applied to it. The second dielectric layer 122 may be used as a capacitance boosting layer, and may increase a capacitance of the capacitor 180 using the ferroelectric or antiferroelectric properties. In example embodiments, the second dielectric layer 122 may be hafnium oxide or zirconium oxide.

The second dielectric layer 122 may be formed of a single dielectric material, and at least two different crystal phases may be mixed in the single dielectric material. Each of the crystal phases included in the second dielectric layer 122 may have ferroelectric or antiferroelectric properties. The second dielectric layer 122 may have different crystal phase boundaries. As a result, when the second dielectric layer 122 has two or more different crystal phases, the second dielectric layer 122 may have a dielectric constant higher than a dielectric constant of a dielectric layer having one crystal phase.

In example embodiments, as shown in FIGS. 1 to 3, a first crystalline portion P1 and a second crystalline portion P2 may be mixed in the second dielectric layer 122. A boundary between the first crystalline portion P1 and the second crystalline portion P2 may extend in a direction protruding from the lower surface of the first dielectric layer 120. For example, in the second dielectric layer 122, the first crystalline portion P1 and the second crystalline portion P2 may be stacked on the surface of the first dielectric layer 120 along a horizontal direction.

In example embodiments, the second dielectric layer 122 may include a tetragonal crystal phase, an orthorhombic crystal phase, or a trigonal crystal phase. For example, the second dielectric layer may have a mixture of the tetragonal crystal phase and the orthorhombic crystal phase. In some embodiments, the second dielectric layer 122 may include a greater proportion of tetragonal crystal phase than the orthorhombic crystal phase.

For example, the second dielectric layer 122 may include hafnium oxide in which the tetragonal crystal phase and the orthorhombic crystal phase are mixed. There may be more tetragonal crystal phases in hafnium oxide than orthorhombic crystal phases. In some embodiments, the second dielectric layer 122 may include zirconium oxide in which the tetragonal crystal phase and the orthorhombic crystal phase are mixed. Similarly, there may be more tetragonal crystal phases in zirconium oxide than orthorhombic crystal phases.

The dielectric layer structure 130 may have a thickness of about 60 Å or less. For example, the dielectric layer structure 130 may have a thickness of about 30 Å to about 60 Å. When the dielectric layer structure 130 is thinner than 30 Å, leakage currents may increase. When the dielectric layer structure 130 is greater than 60 Å, the capacitor may not reach a target capacitance. Therefore, a dielectric layer structure greater than 60 Å may be difficult to apply in a capacitor for a highly integrated semiconductor device. Hereinafter, a thickness of a layer may refer to a thickness of the layer in a direction perpendicular to a surface of underlying layer.

The second dielectric layer 122 may have a thickness that is less than 50% of a total thickness of the dielectric layer structure 130. For example, the second dielectric layer 122 may have a thickness of about 5% to about 50% of the total thickness of the dielectric layer structure 130. Some embodiments of the second dielectric layer 122 have a thickness of about 30 Å or less. For example, the second dielectric layer may have a thickness of about 5 Å to about 30 Å. When the second dielectric layer 122 has a thickness of about 50% or more of the total thickness of the dielectric layer structure 130, the ferroelectric or antiferroelectric properties of the second dielectric layer may be greatly increased, and the capacitance of the capacitor may be unstable. For example, when a thickness of the second dielectric layer 122 is greater than 30 Å, the ferroelectric or antiferroelectric properties of the second dielectric layer may be greatly increased, and thus the capacitance of the capacitor may be unstable. When the second dielectric layer 122 has a thickness of 5% or less of the total thickness of the dielectric layer structure 130, the capacitance may not be effectively increased caused by the ferroelectric or antiferroelectric properties of the second dielectric layer 122. In addition, when a thickness of the second dielectric layer 122 is less than 5 Å, the capacitance may not be effectively increased by the ferroelectric or antiferroelectric properties of the second dielectric layer 122.

The first dielectric layer 120 may be adjacent to the lower electrode 110, and may be positioned under the second dielectric layer 122. The first dielectric layer 120 may have one or more crystal phases. A material of the first dielectric layer 120 may be different from a material of the second dielectric layer 122, and may include a metal oxide. In example embodiments, the first dielectric layer 120 may include hafnium oxide, zirconium oxide, or titanium oxide.

The third dielectric layer 124 may be adjacent to the upper electrode 150, and may be positioned on the second dielectric layer 122. The third dielectric layer 124 may have one or more phases. A material of the third dielectric layer 124 may be different from a material of the second dielectric layer 122, and may include a metal oxide. In example embodiments, the material of the third dielectric layer 124 may be different from a material of the first dielectric layer 120. In some example embodiments, the material of the third dielectric layer 124 may include the same material as a material of the first dielectric layer 120. In example embodiments, the third dielectric layer 124 may include hafnium oxide, zirconium oxide, or titanium oxide.

The dielectric layer structure 130 may include a structure in which hafnium oxide and zirconium oxide are stacked adjacent to each other. For example, the first dielectric layer 120 and the third dielectric layer 124 may each be hafnium oxide or zirconium oxide. Since the hafnium oxide and the zirconium oxide have a small lattice mismatch with each other, residual stress in a stacked structure of the hafnium oxide and the zirconium oxide may be decreased. Further, the titanium oxide has a relatively high dielectric constant. Therefore, since embodiments of the dielectric layer structure 130 include the titanium oxide, a dielectric constant of the dielectric layer structure 130 may be increased.

As described above, embodiments of the dielectric layer structure 130 include the second dielectric layer 122 including the oxide having ferroelectric or antiferroelectric properties and having two or more different crystal phases. Further, the dielectric layer structure 130 may include the first dielectric layer 120 under the second dielectric layer 122 and the third dielectric layer 124 on the second dielectric layer 122, and thus the dielectric layer structure 130 may have a sandwich structure. The first dielectric layer 120 and the third dielectric layer 124 may each have one or more crystal phases. The second dielectric layer 122 may form two or more different crystal phases by (e.g., induced from) the first dielectric layer 120 and the third dielectric layer 124 during forming the dielectric layer structure 130 and from a heat treatment after forming the dielectric layer structure 130.

A stacked structure of the dielectric layer structure 130 may be variously modified according to materials of each of the first to third dielectric layers 120, 122 and 124. Table 1 shows examples of the stacked structure of the dielectric layer structure 130. However, the stacked structure of the dielectric layer structure 130 may be variously modified according to the teachings of the present disclosure, and is therefore not necessarily limited to the examples set forth in Table 1.

TABLE 1

| First dielectric layer | Second dielectric layer | Third dielectric layer |
|---|---|---|
| zirconium oxide | hafnium oxide | titanium oxide |
| titanium oxide | hafnium oxide | zirconium oxide |
| zirconium oxide | hafnium oxide | zirconium oxide |
| hafnium oxide | zirconium oxide | titanium oxide |
| titanium oxide | zirconium oxide | hafnium oxide |
| hafnium oxide | zirconium oxide | hafnium oxide |

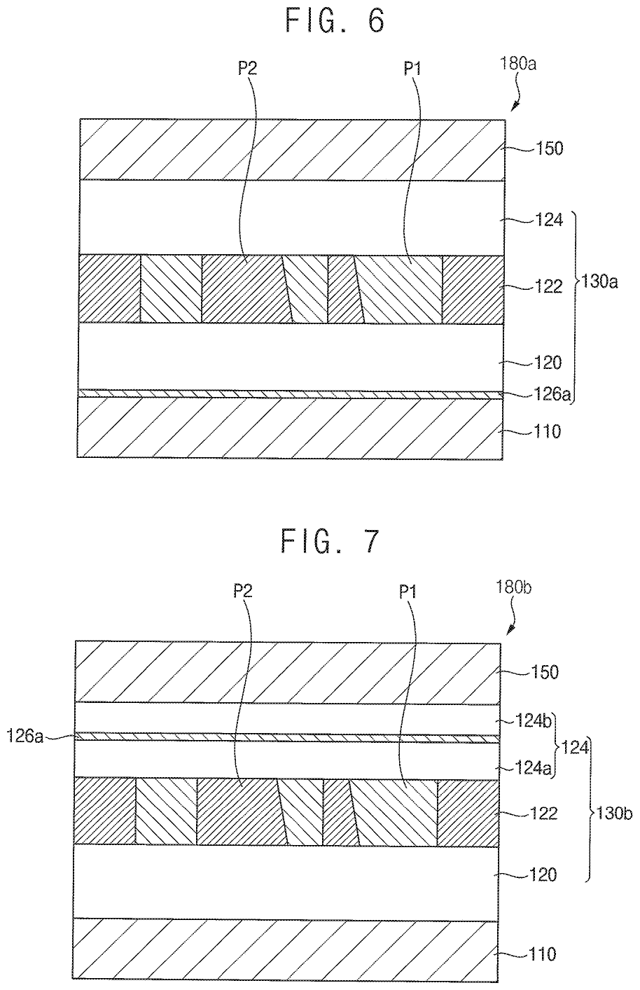

FIG. 5 is a graph that illustrates a dielectric constant according to concentrations of the first crystal phase and the second crystal phase in the second dielectric layer.

In this example, the first crystal phase (phase 1) may be an orthorhombic crystal phase, and the second crystal phase (phase2) may be a tetragonal crystal phase.

Referring to FIG. 5, a dielectric constant of the second dielectric layer in which the first crystal phase and the second crystal phase are mixed may be higher than a dielectric constant of the second dielectric layer including only the first crystal phase. In addition, the dielectric constant of the second dielectric layer in which the first crystal phase and the second crystal phase are mixed may be higher than a dielectric constant of the second dielectric layer including only the second crystal phase. For example, when the second dielectric layer includes about 50% or more of the second crystal phase, the dielectric constant of the second dielectric layer may be increased.

Hereinafter, embodiments of the capacitor are described. Capacitors described below are similar to the capacitors described with reference to FIGS. 1 to 4, except for variances in the dielectric layer structure. Therefore, only the dielectric layer structure is mainly described. Further, each of the capacitors shown in the following examples includes a lower electrode having flat plate shape, though other lower electrode shapes may be used.

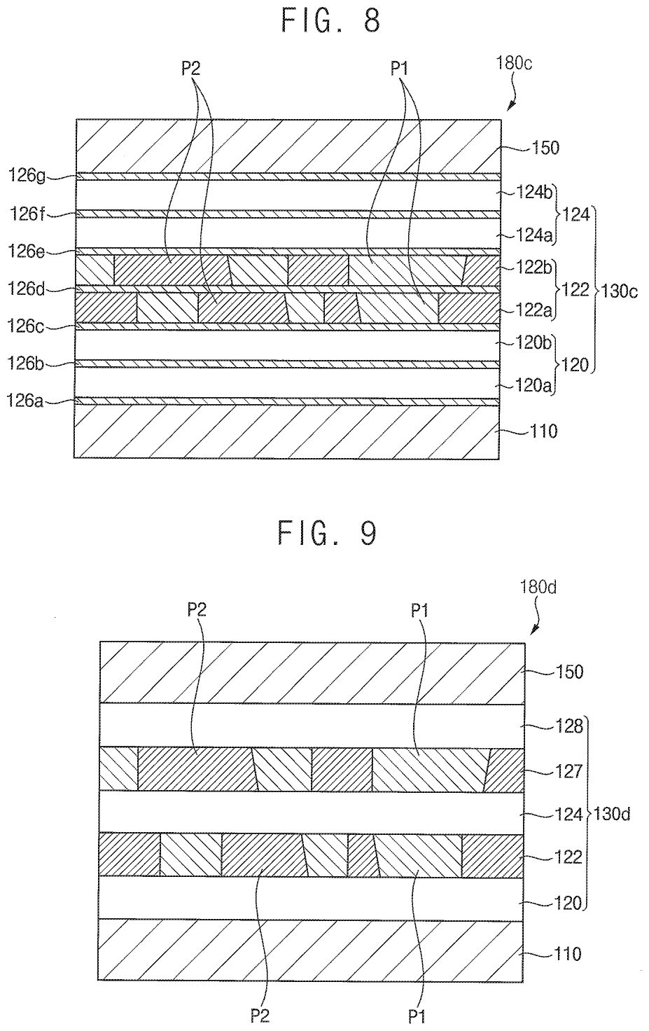

FIG. 6 is a cross-sectional view that illustrates a capacitor in accordance with example embodiments.

Referring to FIG. 6, the capacitor 180a may include the lower electrode 110, a dielectric layer structure 130a, the upper electrode 150 stacked.

The dielectric layer structure 130a may have a structure in which the first dielectric layer 120, the second dielectric layer 122, and the third dielectric layer 124 are stacked, and may further include at least one insert layer 126a. The insert layer 126a may be included in at least one of boundaries between the lower electrode 110, the first to third dielectric layers 120, 122 and 124, and the upper electrode 150. In example embodiments, the dielectric layer structure 130a may include one to three insert layers. The first to third dielectric layers 120, 122 and 124 may be substantially the same as or similar to those described with reference to FIGS. 1 to 4.

The insert layer 126a may include Al2O3, Y2O3, Nb2O5, Ta2O5, MoO3, RuO2, V2O5, or La2O3, though the constituent materials of the insert layer 126a are not necessarily limited thereto.

As the dielectric layer structure 130a may further include the insert layer 126a, a crystallinity of the first to third dielectric layers 120, 122, and 124 may be increased, and leakage currents may be decreased.

For example, as shown in FIG. 6, the capacitor 180a may include the lower electrode 110, the insert layer 126a, the first dielectric layer 120, the second dielectric layer 122 and the third dielectric layer 124 in a stacked structure.

The dielectric layer structure 130a may have a thickness of about 60 Å or less. For example, the dielectric layer structure 130a may have a thickness of about 30 Å to about 60 Å. The second dielectric layer 122 may have a thickness less than 50% of a total thickness of the dielectric layer structure 130a. For example, the second dielectric layer 122 may have a thickness of 5 to 50% of the total thickness of the dielectric layer structure 130a. The second dielectric layer 122 may have a thickness of about 30 Å or less.

A stacked structure of the dielectric layer structure 130a may vary according to the positions of the insert layers 126a and the number of the insert layers 126a. For example, the stacked structure of the dielectric layer structure 130a formed on the lower electrode 110 may be as follows:

1) lower electrode/insert layer/first dielectric layer/second dielectric layer/third dielectric layer.

2) lower electrode/first dielectric layer/insert layer/second dielectric layer/third dielectric layer.

3) lower electrode/first dielectric layer/second dielectric layer/insert layer/third dielectric layer.

4) lower electrode/first dielectric layer/second dielectric layer/third dielectric layer/insert layer.

5) lower electrode/insert layer1/first dielectric layer/insert layer 2/second dielectric layer/third dielectric layer.

6) lower electrode/insert layer1/first dielectric layer/second dielectric layer/insert layer2/third dielectric layer.

7) lower electrode/insert layer1/first dielectric layer/second dielectric layer/third dielectric layer/insert layer 2.

8) lower electrode/first dielectric layer/insert layer 1/second dielectric layer/insert layer 2/third dielectric layer.

9) lower electrode/first dielectric layer/insert layer 1/second dielectric layer/third dielectric layer/insert layer 2.

10) lower electrode/insert layer 1/first dielectric layer/insert layer 2/second dielectric layer/insert layer 3/third dielectric layer.

11) lower electrode/insert layer 1/first dielectric layer/insert layer 2/second dielectric layer/third dielectric layer/insert layer 3.

12) lower electrode/first dielectric layer/insert layer 1/second dielectric layer/insert layer 2/third dielectric layer/insert layer 3.

13) lower electrode/insert layer 1/first dielectric layer/insert layer 2/second dielectric layer/insert layer 3/third dielectric layer/insert layer 4.

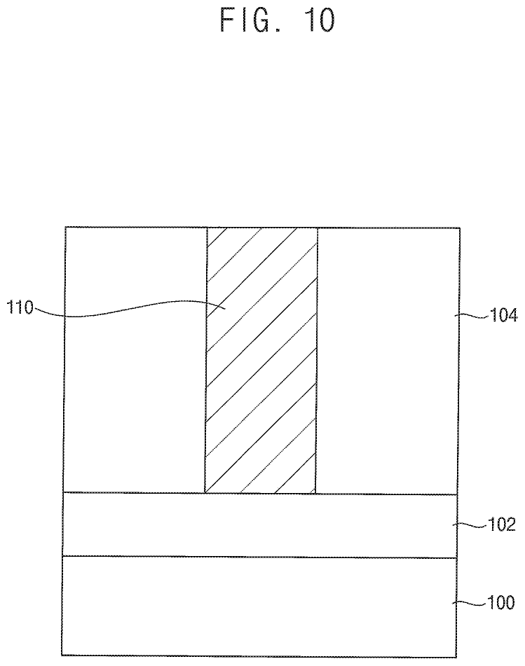

FIG. 7 is a cross-sectional view that illustrates a capacitor in accordance with example embodiments.

Referring to FIG. 7, the capacitor 180b may include the lower electrode 110, a dielectric layer structure 130b and the upper electrode 150 in a stacked structure.

The dielectric layer structure 130b may include the first dielectric layer 120, the second dielectric layer 122 and the third dielectric layer 124 in a stacked structure, and may further include at least one insert layer 126a. The insert layer 126a may be included in an inside of the first dielectric layer 120, an inside of the second dielectric layer 122 and/or an inside of the third dielectric layer 124. In example embodiments, one to three insert layers may be included in the dielectric layer structure 130b. The first to third dielectric layers 120, 122 and 124 may be the same as or similar to the first to third dielectric layers described with reference to FIGS. 1 to 4.

When an insert layer is included in any of the dielectric layers, the dielectric layer may be separated to have a lower dielectric layer and an upper dielectric layer by the insert layer 126a.

For example, as shown in FIG. 7, when the insert layer 126a is included in the third dielectric layer 124, the third dielectric layer 124 may be separated to have a third lower dielectric layer 124a and a third upper dielectric layer 124b by the insert layer 126a. That is, the third dielectric layer 124 may include the third lower dielectric layer 124a, the third upper dielectric layer 124b, and the insert layer 126a between the third lower dielectric layer 124a and the third upper dielectric layer 124b. Therefore, the capacitor may include the lower electrode 110, the first dielectric layer 120, the second dielectric layer 122, the third lower dielectric layer 124a, the insert layer 126a, the third upper dielectric layer 124b in a sequentially stacked structure.

The insert layer 126a may include, e.g., Al2O3, Y2O3, Nb2O5, Ta2O5, MoO3, RuO2, V2O5, or La2O3.

The dielectric layer structure 130b may have a thickness of 60 or less. For example, the dielectric layer structure 130b may have a thickness of about 30 Å to about 60 Å. The second dielectric layer 122 may have a thickness less than about 50% of the total thickness of the dielectric layer structure 130b. For example, the second dielectric layer 122 may have a thickness of about 5 to about 50% of the total thickness of the dielectric layer structure 130b. The second dielectric layer 122 may have a thickness of about 30 Å or less.

A stacked structure of the dielectric layer structure 130b may vary according to the position of the insert layer 126a and the number of the insert layers 126a. For example, the stacked structure of the dielectric layer structure 130b may be as follows:

1) first lower dielectric layer/insert layer/first upper dielectric layer/second dielectric layer/third dielectric layer.

2) first dielectric layer/second lower dielectric layer/insert layer/second upper dielectric layer/third dielectric layer.

3) first dielectric layer/second dielectric layer/third lower dielectric layer/insert layer/third upper dielectric layer.

4) first lower dielectric layer/insert layer 1/first upper dielectric layer/second lower dielectric layer/insert layer 2/second upper dielectric layer/third dielectric layer.

5) first lower dielectric layer/insert layer 1/first upper dielectric layer/second dielectric layer/third lower dielectric layer/insert layer 2/third upper dielectric layer.

6) first dielectric layer/second lower dielectric layer/insert layer 1/second upper dielectric layer/third lower dielectric layer/insert layer 2/third upper dielectric layer.

7) first lower dielectric layer/insert layer 1/first upper dielectric layer/second lower dielectric layer/insert layer 2/second upper dielectric layer/third lower dielectric layer/insert layer 3/third upper dielectric layer.

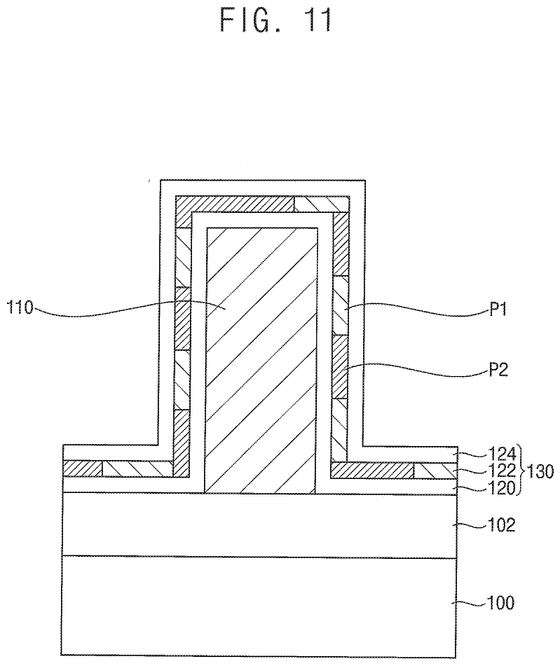

FIG. 8 is a cross-sectional view that illustrates a capacitor in accordance with example embodiments.

Referring to FIG. 8, the capacitor 180c may include the lower electrode 110, a dielectric layer structure 130c, and the upper electrode 150 in a stacked structure.

The dielectric layer structure 130c may include the first dielectric layer 120, the second dielectric layer 122 and the third dielectric layer 124 in a stacked structure, and may further include a plurality of insert layers. The insert layers may be included in, for example, an inside of the first dielectric layer 120, an inside of the second dielectric layer 122, and an inside of the third dielectric layer 124, and at least one of the boundaries between the first to third dielectric layers 120, 122 and 124.

For example, the dielectric layer structure 130c may include any one of the dielectric layer structures described with reference to FIG. 6, and further include one insert layer disposed in the inside of the first dielectric layer 120, the inside of the second dielectric layer 122 and/or the inside of the third dielectric layer 124. For example, seven insert layers may be included in the dielectric layer structure 130c.

As shown in FIG. 8, when the dielectric layer structure 130c has seven insert layers, the dielectric layer structure 130c may include: inserted layer 1 126a/first lower dielectric layer 120a/inserted layer2 126b/first upper dielectric layer 120b/insert layer 3 126c/second lower dielectric layer 122a/insert layer 4 126d/second upper dielectric layer 122b/insert layer 5 126e/third lower dielectric layer 124a/insert layer 6 126f/third upper dielectric layer 124b/insert layer 7 126g in a sequentially stacked structure.

The insert layer may include, e.g., Al2O3, Y2O3, Nb2O5, Ta2O5, MoO3, RuO2, V2O5, or La2O3.

The dielectric layer structure 130c may have a thickness of 60 Å or less. For example, the dielectric layer structure 130c may have a thickness of 30 Å to 60 Å. The second dielectric layer 122 may have a thickness less than 50% of a total thickness of the dielectric layer structure 130c. For example, the second dielectric layer 122 may have a thickness of 5 to 50% of the total thickness of the dielectric layer structure 130c. The second dielectric layer 122 may have a thickness of 30 Å or less.

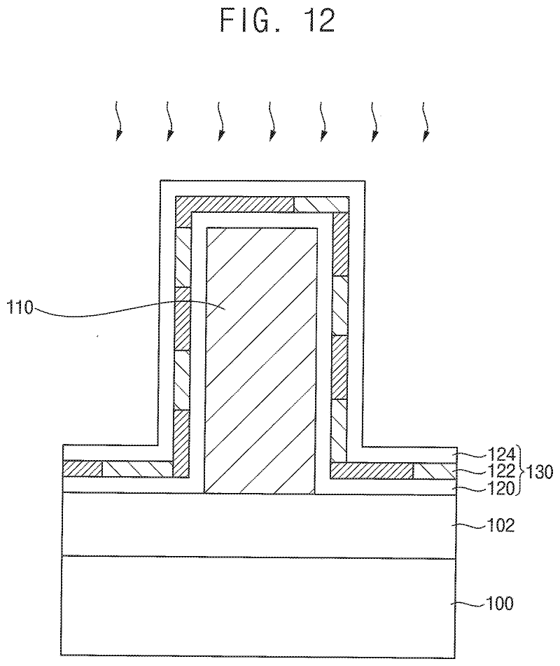

FIG. 9 is a cross-sectional view that illustrates a capacitor in accordance with example embodiments.

Referring to FIG. 9, the capacitor 180d may include the lower electrode 110, a dielectric layer structure 130d, and the upper electrode 150 in a stacked structure.

The dielectric layer structure 130d may include the first dielectric layer 120, the second dielectric layer 122, the third dielectric layer 124, the fourth dielectric layer 127 and the fifth dielectric layer 128 in a stacked structure. The first to third dielectric layers 120, 122 and 124 may be the same as or similar to the first to third dielectric layers described with reference to FIGS. 1 to 4.

The fourth dielectric layer 127 may be the same as or similar to the second dielectric layer 122. For example, the fourth dielectric layer 127 may be formed of a single dielectric material, and at least two different crystal phases may be mixed in the single dielectric material. Each of the crystal phases included in the fourth dielectric layer 127 may have a ferroelectric property or an antiferroelectric property. The fifth dielectric layer 128 may be the same as or similar to the first dielectric layer 120 or the third dielectric layer 124.

For example, in the dielectric layer structure 130d, the second and fourth dielectric layers 122 and 127 may be used as capacitance boosting layers for increasing a capacitance of the capacitor 180d using the ferroelectric or antiferroelectric properties. Two or more capacitance boosting layers may be included in the dielectric layer structure 130d. As dielectric layers may be formed on and under the capacitance boosting layer, the dielectric layer, the capacitance boosting layer and the dielectric layer may have a sandwich structure. Although it is illustrated that two capacitance boosting layers are included in the dielectric layer structure 130d, it is not limited thereto, and more capacitance boosting layers may be included.

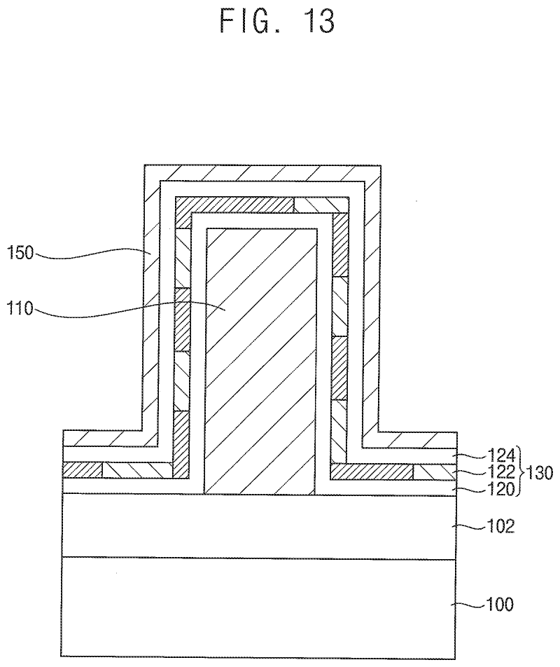

FIGS. 10 to 13 are cross-sectional views that illustrate a method of manufacturing a capacitor in accordance with example embodiments.

Hereinafter, an example of a method of manufacturing a capacitor including a lower electrode with a pillar shape is described.

Referring to FIG. 10, a lower structure 102 which may include lower circuits such as a transistor, a contact plug, and a conductive line and an insulating interlayer covering the lower circuits may be formed on a substrate 100.

A mold layer 104 including a hole may be formed on the lower structure 102. The hole may be a region for forming a lower electrode.

A lower electrode layer may be formed on the mold layer 104 to fill the hole. The lower electrode layer may be planarized until an upper surface of the mold layer 104 is exposed to form the lower electrode 110.

In example embodiments, the lower electrode layer may be deposited by a deposition process such as physical vapor deposition (PVD), chemical vapor deposition (CVD), and atomic layer deposition (ALD) process. In addition, the planarization process may include a chemical mechanical polishing process and/or an etch-back process.

In some example embodiments, the lower electrode 110 may be formed by forming a lower electrode layer on the lower structure 102 and patterning the lower electrode layer by a photolithography process. In this case, the mold layer may not be formed.

Referring to FIG. 11, the mold layer may be removed. Therefore, the lower electrode 110 having a pillar shape and an upper surface thereof may be exposed.

A first dielectric layer 120 may be formed on surfaces of the lower electrode 110 and the lower structure 102 to have a uniform thickness. A second dielectric layer 122 may be formed on the first dielectric layer 120. Also, a third dielectric layer 124 may be formed on the second dielectric layer 122. Therefore, a dielectric layer structure 130 in which the first dielectric layer 120, the second dielectric layer 122 and the third dielectric layer 124 are stacked may be formed on the lower electrode 110 and the lower structure 102.

The second dielectric layer 122 may be an oxide that may have ferroelectric or antiferroelectric properties depending on electric fields. For example, the second dielectric layer 122 may include an oxide that exhibits either ferroelectric or antiferroelectric properties in the presence of different electric fields. In example embodiments, the second dielectric layer 122 may be hafnium oxide or zirconium oxide. The second dielectric layer 122 may be formed of a single dielectric material, and at least two different crystal phases may be mixed in the single dielectric material. In example embodiments, a first crystalline portion P1 and a second crystalline portion P2 may be mixed in the second dielectric layer 122.

In example embodiments, the second dielectric layer 122 may be hafnium oxide in which a tetragonal crystal phase and an orthorhombic crystal phase are mixed. In some example embodiments, the second dielectric layer 122 may be zirconium oxide in which a tetragonal crystal phase and an orthorhombic crystal phase are mixed.

The first dielectric layer 120 may have one or more crystal phases. The first dielectric layer 120 may include a material that is different than a material of the second dielectric layer 122, and may include a metal oxide. In example embodiments, the first dielectric layer 120 may include hafnium oxide, zirconium oxide, or titanium oxide.

The third dielectric layer 124 may have one or more phases. The third dielectric layer 124 may include a material that is different than the material of the second dielectric layer 122, and may include a metal oxide. In example embodiments, the third dielectric layer 124 may include hafnium oxide, zirconium oxide, or titanium oxide.

The dielectric layer structure 130 may have a thickness of 60 Å or less. For example, the dielectric layer structure 130 may have a thickness of 30 Å to 60 Å. The second dielectric layer 122 may have a thickness smaller than 50% of a total thickness of the dielectric layer structure 130. For example, the second dielectric layer 122 may have a thickness of 5 to 50% of the total thickness of the dielectric layer structure 130. The second dielectric layer 122 may have a thickness of 30 Å or less.

The first to third dielectric layers 120, 122 and 124 may be formed by an atomic layer deposition process (ALD). The first to third dielectric layers 120, 122 and 124 may be deposited at a temperature of 200° C. to 400° C. The deposition temperature of each of the first to third dielectric layers 120, 122 and 124 may be the same or different from each other and within the temperature range. In a comparative example, when the deposition temperature is lower than 200° C., thermal decomposition of precursors may not be performed. Thus, it is difficult to normally deposit the first to third dielectric layers 120, 122 and 124. Further, when the deposition temperature is higher than 400° C., the first to third dielectric layers 120, 122 and 124 may not be stably grown. Accordingly, the deposition process may be performed within a temperature range of 200° C. to 400° C.

As described above, when the dielectric layer structure 130 including the first to third dielectric layers 120, 122 and 124 is formed to have a thickness of 60 Å or less, the second dielectric layer 122 having two or more crystal phases may be formed by the first and third dielectric layers 120 and 124 formed under and on the second dielectric layer 122.

For example, when the dielectric layer structure in which a zirconium oxide layer, a hafnium oxide layer and a titanium oxide layer are stacked is formed, the hafnium oxide layer may be formed to have a mixture of the tetragonal crystal phase and the orthorhombic crystal phases due to an influence of a crystal phase of the zirconium oxide layer and a crystal phase of the titanium oxide layer. Accordingly, the crystal phase(s) of the second dielectric layer 122 may be influenced by the first dielectric layer 120 and the third dielectric layer 124.

In example embodiments, the first to third dielectric layers 120, 122 and 124 may be respectively formed in different reaction chambers of the same deposition apparatus. In some example embodiments, the first to third dielectric layers 120, 122 and 124 may be formed in the same reaction chamber of the same deposition apparatus.

In some example embodiments, at least one insert layer may be further formed while the first to third dielectric layers 120, 122 and 124 are formed. A deposition process of the insert layer may be performed at a temperature of 200° C. to 400° C. The dielectric layer structure including at least one insert layer may be formed by performing the deposition process of the insert layer and subsequent processes. For example, when the insert layer is formed, one of the capacitors described with reference to FIGS. 6 to 8 may be formed.

In example embodiments, after forming the first dielectric layer 120 and/or after forming the second dielectric layer 122, a heat treatment process may be selectively performed. In example embodiments, the heat treatment process may be performed at a temperature in the range of 350° C. to 600° C. The heat treatment process may be performed in an N2, O2 or H2 atmosphere.

When the heat treatment process is performed, the first to third dielectric layers 120, 122 and 124 may be additionally crystallized. When the heat treatment temperature is lower than 350° C., the crystallization effect of the first to third dielectric layers 120, 122 and 124 may be reduced. When the heat treatment temperature is higher than 600° C., diffusion or agglomeration of metals included in a capacitor may occur due to, for example, a heat budget.

Referring to FIG. 12, a heat treatment process may be performed on the dielectric layer structure 130. The first to third dielectric layers 120, 122 and 124 included in the dielectric layer structure 130 may be additionally crystallized by the heat treatment process. Therefore, the dielectric layer structure 130 may have high crystallinity.

The heat treatment process may be performed at a temperature higher than the deposition temperature of each of the first to third dielectric layers 120, 122 and 124 included in the dielectric layer structure 130. In example embodiments, the heat treatment process may be performed at a temperature in the range of 350° C. to 600° C.

Referring to FIG. 13, an upper electrode 150 may be formed on the dielectric layer structure 130.

In example embodiments, the upper electrode 150 may be formed of the same material as the lower electrode 110 or a material different from a material of the lower electrode 110.

In example embodiments, the upper electrode 150 may be formed by a deposition process such as physical vapor deposition (PVD), chemical vapor deposition (CVD), and atomic layer deposition (ALD) processes.

In example embodiments, after forming the upper electrode 150, another heat treatment process may be performed. The first to third dielectric layers 120, 122 and 124 included in the dielectric layer structure 130 may be additionally crystallized by this heat treatment process. In example embodiments, the heat treatment process may be performed at a temperature higher than the deposition temperature of the dielectric layer structure 130.

As described above, the second dielectric layer 122 may be an oxide with ferroelectric or antiferroelectric properties which vary depending on electric fields. The second dielectric layer 122 included in the dielectric layer structure 130 may be formed of a single dielectric material in which at least two different crystal phases are mixed. In this case, the dielectric constant of the second dielectric layer 122 may be increased, so that the capacitance of the capacitor may be increased.

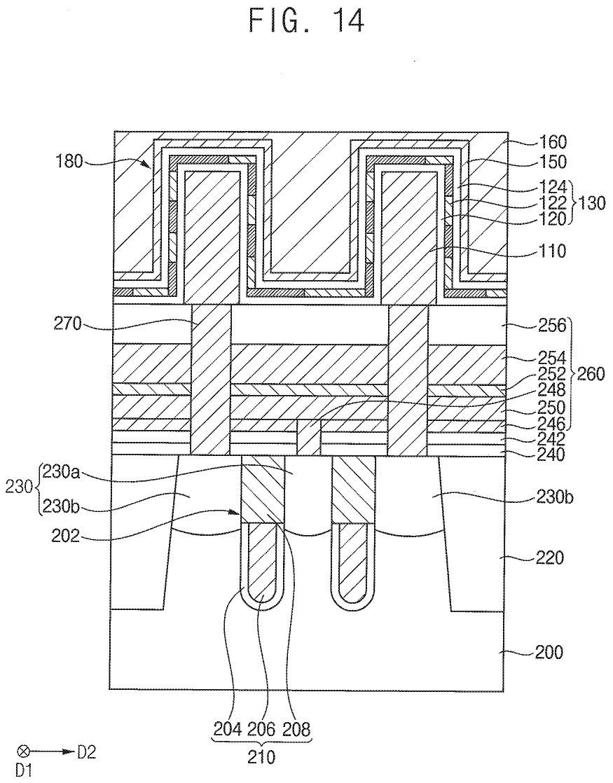

FIG. 14 is a cross-sectional view that illustrates a DRAM device having a capacitor structure in accordance with example embodiments.

Although the DRAM memory device is disclosed in FIG. 14, the capacitor may be applied to many electronic devices and semiconductor devices, including other memory devices that use the capacitor as a data storage unit.

Referring to FIG. 14, the DRAM device may include a cell transistor, a capacitor, and a bit line structure formed on a substrate. A unit cell of the DRAM device may include one cell transistor and one capacitor.

The substrate 200 may include an active region and a field region. The field region may be a region in which an isolation layer 220 is formed in an isolation trench included in the substrate 200. The active region may be a region other than the field region.

A gate trench 202 may be formed at an upper portion of the substrate 200. The gate trench 202 may extend in a first direction D1 parallel to an upper surface of the substrate 200. A gate structure 210 may be formed in the gate trench 202.

In example embodiments, the gate structure 210 may include a gate insulation layer 204, a gate electrode 206 and a capping insulation pattern 208. A plurality of the gate structures 210 may be arranged in a second direction D2 perpendicular to the first direction D1 and parallel to the upper surface of the substrate 200.

The gate insulation layer 204 may include silicon oxide. The gate electrode 206 may include a metal material and/or polysilicon. The capping insulation pattern 208 may include silicon nitride.

An impurity region 230 serving as a source/drain region may be formed at the substrate 100 in the active region between the gate structures 210. For example, the substrate 100 may include a first impurity region 230a electrically connected to the bit line structure 260 and a second impurity region 230b electrically connected to the capacitor 180.

A pad insulation pattern 240, a first etch stop pattern 242, and a first conductive pattern 246 may be formed on the active region, the isolation layer 220 and the gate structure 210. The pad insulation pattern 240 may include, e.g., an oxide such as silicon oxide, and the first etch stop pattern 242 may include, e.g., a nitride such as silicon nitride. The first conductive pattern 246 may include, e.g., polysilicon doped with impurities.

A recess may be formed at the substrate 100 between stacked structures of the pad insulation pattern 240, the first etch stop pattern 242 and the first conductive pattern 246. The recess may be disposed in a portion of the substrate 100 between the gate structures. An upper surface of the first impurity region 230a may be exposed by a bottom of the recess.

A second conductive pattern 248 may be formed in the recess. The second conductive pattern 248 may include, e.g., polysilicon doped with impurities. The second conductive pattern 248 may contact the first impurity region 230a.

A third conductive pattern 250 may be formed on the first conductive pattern 246 and the second conductive pattern 248. The third conductive pattern 250 may include, e.g., polysilicon doped with impurities. As the first to third conductive patterns 246, 248 and 250 may each include substantially the same material, in some embodiments, the first to third conductive patterns 246, 248 and 250 may be merged into one pattern or into a continuous portion. A barrier metal pattern 252, a metal pattern 254 and a hard mask pattern 256 may be sequentially stacked on the third conductive pattern 250.

A stacked structure of the first conductive pattern 246, the second conductive pattern 248, the third conductive pattern 250, the barrier metal pattern 252, the metal pattern 254 and the hard mask pattern 256 may serve as the bit line structure 260.

For example, the second conductive pattern 248 may serve as a bit line contact, and the first conductive pattern 246, the third conductive pattern 250, the barrier metal pattern 252 and the metal pattern 254 may serve as a bit line. The bit line structure 260 may extend in the second direction D2. A plurality of bit line structures 260d may be arranged in the first direction D1.

In example embodiments, a spacer may be formed on a sidewall of the bit line structure 260. A first insulating interlayer may be formed to fill a space between the bit line structures 260.

A contact plug 270 may be formed through the first insulating interlayer, the first etch stop pattern 242 and the pad insulation pattern 240. The contact plug 270 may contact the second impurity region 230b. The contact plug 270 may be formed between the bit line structures 260.

A capacitor 180 may be formed on the contact plug 270. The capacitor 180 may include the lower electrode 110, the dielectric layer structure 130, and the upper electrode 150. The dielectric layer structure 130 may include at least the first dielectric layer 120, the second dielectric layer 122, and the third dielectric layer 124.

The capacitor 180 may have a structure similar to the capacitor described with reference to FIG. 1, or the capacitor 180 may have a structure of one of the capacitors described with reference to FIGS. 6 to 8. In other examples, the capacitor may have another structure similar to the embodiments described herein with modifications made thereto in accordance with the present disclosure.

A plate electrode 160 may be further formed on the upper electrode 150. The plate electrode 160 may include doped polysilicon.

The dielectric layer structure may have a high dielectric constant, and thus the capacitance of the capacitor may be greatly increased. Therefore, the DRAM device may have increased performance, reduced leakage current, and increased reliability.

The foregoing is illustrative of example embodiments and is not to be construed as limiting thereof. Although a few example embodiments have been described, those skilled in the art will readily appreciate that many modifications are possible in the example embodiments without materially departing from the novel teachings and advantages of the present inventive concept. Accordingly, all such modifications are intended to be included within the scope of the present inventive concept as defined in the claims.

What is claimed is:

1. A capacitor, comprising:
a lower electrode;
a dielectric layer structure disposed on the lower electrode, the dielectric layer structure including a first dielectric layer, a second dielectric layer contacting the first dielectric layer, and a third dielectric layer contacting the second dielectric layer; and
an upper electrode disposed on the dielectric layer structure,
wherein each of the first, second, and third dielectric layers includes a material with a crystalline structure, the second dielectric layer includes an oxide having ferroelectric or antiferroelectric properties, and wherein the second dielectric layer includes a material with at least two different crystal phases.

2. The capacitor of claim 1, wherein the second dielectric layer includes a hafnium oxide layer or a zirconium oxide layer.

3. The capacitor of claim 1, wherein the second dielectric layer includes a mixture of a tetragonal crystal phase and an orthorhombic crystal phase.

4. The capacitor of claim 1, wherein at least two crystal phases included in the second dielectric layer are stacked and arranged across a surface of the first dielectric layer.

5. The capacitor of claim 1, wherein a material of the first dielectric layer and a material of the third dielectric layer are different from a material of the second dielectric layer, and wherein the first and third dielectric layers include a zirconium oxide layer, a hafnium oxide layer, or a titanium oxide layer.

6. The capacitor of claim 5, wherein at least one of the first dielectric layer and the third dielectric layer is a hafnium oxide layer or a zirconium oxide layer.

7. The capacitor of claim 1, wherein the first and third dielectric layers each have at least one crystal phase.

8. The capacitor of claim 1, wherein the dielectric layer structure has a thickness of 30 Å to 60 Å.

9. The capacitor of claim 1, wherein the second dielectric layer has a thickness of 5 Å to 30 Å.

10. The capacitor of claim 1, wherein the dielectric layer structure further includes at least one insert layer.

11. The capacitor of claim 10, wherein the insert layer is included in a boundary between the lower electrode and the dielectric layer structure, a boundary between the dielectric layer structure and the upper electrode, an inside region of the first dielectric layer, an inside region of the second dielectric layer, or an inside region of the third dielectric layer.

12. The capacitor of claim 10, wherein the insert layer includes Al2O3, Y2O3, Nb2O5, Ta2O5, MoO3, RuO2, V2O5, or La2O3.

13. A capacitor, comprising:
a lower electrode;
a dielectric layer structure disposed on the lower electrode, the dielectric layer structure including a first dielectric layer, a third dielectric layer, and a second dielectric layer adjacent to the first dielectric layer and the third dielectric layer; and
an upper electrode disposed on the dielectric layer structure,
wherein the dielectric layer structure has a thickness of 30 Å to 60 Å in a thickness direction perpendicular to an upper surface of the lower electrode,
wherein the second dielectric layer includes hafnium oxide or zirconium oxide, and the second dielectric layer includes one material in which at least two different crystal phases are mixed, and
wherein a thickness of the second dielectric layer is less than 50% of a total thickness of the dielectric layer structure.

14. The capacitor of claim 12, wherein the second dielectric layer includes a mixture of a tetragonal crystal phase and an orthorhombic crystal phase.

15. The capacitor of claim 12, wherein a material of the first dielectric layer and a material of the third dielectric layer are different from a material of the second dielectric layer, and wherein each of the first and third dielectric layers includes a zirconium oxide layer, a hafnium oxide layer, or a titanium oxide layer.

16. The capacitor of claim 12, wherein the dielectric layer structure further includes at least one insert layer.

17. The capacitor of claim 15, wherein the insert layer includes Al2O3, Y2O3, Nb2O5, Ta2O5, MoO3, RuO2, V2O5, or La2O3.

18. The capacitor of claim 12, wherein each of the first to third dielectric layers has a material with a crystalline structure.

19. A DRAM device, comprising:
a cell transistor disposed on a substrate, the cell transistor including a gate structure, a first impurity region, and a second impurity region;
a bit line structure electrically connected to the first impurity region and including a plurality of bit line structures;
a contact plug contacting the second impurity region, the contact structure disposed between adjacent bit line structures of the plurality of bit line structures; and
a capacitor disposed on the contact structure, the capacitor electrically connected to the second impurity region,
wherein the capacitor comprises:
a lower electrode;
a dielectric layer structure disposed on the lower electrode, the dielectric layer structure including a first dielectric layer, a second dielectric layer, and a third dielectric layer sequentially stacked; and
an upper electrode disposed on the dielectric layer structure,
wherein the second dielectric layer includes hafnium oxide or zirconium oxide, the second dielectric layer includes a material in which a tetragonal crystal phase and an orthorhombic crystal phase are mixed, and
wherein the tetragonal crystal phase and the orthorhombic crystal phases included in the second dielectric layer are stacked on along a surface of the first dielectric layer.

20. The DRAM device of claim 18, wherein a material of the first dielectric layer and a material of the third dielectric layer are different from a material of the second dielectric layer, and wherein each of the first and third dielectric layers include a zirconium oxide layer, hafnium oxide layer, or titanium oxide layer having a crystalline structure.
